(19) United States
(12) Patent Application Publication
(10) Pub. No.: US 2025/0372371 A1
(43) Pub. Date: Dec. 4, 2025

(54) PROCESS FOR FABRICATING A STRUCTURE COMPRISING A LAYER THAT ACTS AS A BARRIER TO DIFFUSION OF ATOMIC SPECIES

(71) Applicant: Soitec, BERNIN (FR)

(72) Inventors: Marcel Broekaart, BERNIN (FR); Rénald Guerin, BERNIN (FR); Morgane Logiou, BERNIN (FR); Isabelle Bertrand, BERNIN (FR)

(21) Appl. No.: 18/880,143

(22) PCT Filed: Jun. 20, 2023
(86) PCT No.: PCT/EP2023/066668

§ 371 Date: Dec. 30, 2024

(30) Foreign Application Priority Data
Jul. 4, 2022 (FR) FR2206733

(51) Int. Cl. H01L 21/02

(52) U.S. Cl. CPC H01L 21/02362; H01L 21/02164; H01L 21/02238; H01L 21/02323; H01L 21/02332; H01L 21/0234

(57) ABSTRACT

A method is used to fabricate a structure comprising a thin layer bonded to a carrier by way of a dielectric layer, the carrier comprising a charge-trapping layer placed on the surface of a base substrate. The method includes applying a surface treatment to an exposed surface of the main face of the carrier and/or to an exposed surface of the main face of the donor substrate to form thereon a layer that acts as a barrier to the diffusion of certain atomic species. This surface treatment involves exposing the exposed surface to an oxygen-containing plasma, and then exposing the exposed surface to a nitrogen-containing plasma.

### CROSS-REFERENCE TO RELATED APPLICATIONS

This application is a national phase entry under 35 U.S.C. § 371 of International Patent Application PCT/EP2023/066668, filed Jun. 20, 2023, designating the United States of America and published as International Patent Publication WO 2024/008441 A1 on Jan. 11, 2024, which claims the benefit under Article 8 of the Patent Cooperation Treaty of French Patent Application Serial No. FR2206733, filed Jul. 4, 2022.

### TECHNICAL FIELD

The disclosure relates to a method for manufacturing a structure comprising a thin layer transferred onto a support provided with a charge-trapping layer. The disclosure is particularly useful in the fields of microelectronics, microsystems, photonics, etc.

### BACKGROUND

Document WO2021008742 points out that it is often advantageous to provide an electric charge-trapping layer (more concisely referred to as a “trapping layer” in the remainder of this description) in the support of a structure formed by a thin layer transferred, via a dielectric layer, onto this support. The manufacture of this type of structure is disclosed, for example, in documents FR2860341, FR2933233, FR2953640, US2015115480, U.S. Pat. Nos. 7,268,060 and 6,544,656. In particular, it can be used to shape electronic or electroacoustic components in the field of radio frequency (RF) signals.

The thin film, often monocrystalline, can be semiconducting (e.g., silicon) or insulating (e.g., a piezoelectric material such as lithium tantalate or lithium niobate).

The aforementioned document also discloses the fact that this type of structure is particularly sensitive to hydrogen, as this atomic species can diffuse and congeal in the trapping layer, which tends to passivate the electrical defects that this layer comprises and, as a result, degrade the structure's RF performance. As documented in the publication “White paper-RF SOI Characterization,” dated January 2015 and published by SOITEC, the RF performance of a substrate can be characterized by a second harmonic distortion measurement.

The applicant also observed that when the thin film comprised lithium, this atomic species was also likely to diffuse into the structure during the steps of its manufacture, congeal in the trapping layer, and dope the trapping layer. As with hydrogen, the presence of lithium in the trapping layer tends to degrade the RF performance of the structure.

To prevent RF performance degradation caused by the diffusion of atomic species (particularly hydrogen) in a structure having a trapping layer, document WO2021008742 proposes integrating a diffusion barrier into the dielectric layer.

### BRIEF SUMMARY

One aim of the present disclosure is to improve this state of the art by proposing a particularly simple and effective method for incorporating a diffusion barrier to certain atomic species, especially hydrogen and/or lithium, in a structure comprising a charge-trapping layer.

With a view to achieving this aim, the present disclosure proposes a method for manufacturing a structure comprising a thin layer transferred onto a support by way of a dielectric layer, the support comprising an electric charge-trapping layer superficially arranged on a base substrate, the method comprising the following steps:
forming a dielectric layer on an exposed surface of a so-called “main” face of the support and/or on an exposed surface of a so-called “main” face of a donor substrate;
applying a surface treatment to the exposed surface of the main face of the support and/or to the exposed surface of the main face of the donor substrate with a view to forming thereon a layer that acts as a barrier to the diffusion of certain atomic species;
assembling the support and the donor substrate by their respective main faces to form an intermediate structure; and
removing at least part of the donor substrate from the intermediate structure to form the thin layer.

The surface treatment applied to at least one of the exposed surfaces comprises:
exposing the exposed surface to a plasma comprising oxygen to form a damaged thickness beneath the main surface, then
exposing the exposed surface to a plasma comprising nitrogen to nitride the damaged thickness.

Such a surface treatment simply forms a layer that acts as a barrier to the diffusion of certain atomic species, which is particularly effective against the diffusion of hydrogen and/or lithium. As a result, this avoids the formation of a structure with degraded RF performance.

According to other advantageous non-limiting features of the disclosure, taken alone or according to any technically feasible combination:
the donor substrate comprises a monocrystalline piezoelectric material;
the donor substrate is a monocrystalline silicon substrate;
the base substrate is a monocrystalline silicon substrate;
the dielectric layer comprises silicon oxide;
the trapping layer is made of polycrystalline silicon;
the formation of the dielectric layer comprises oxidation of the trapping layer;
the formation of the dielectric layer precedes the application of the surface treatment to the exposed surface of the main face of the support;
the dielectric layer follows the application of the surface treatment to the exposed surface of the main face of the support;
the silicon oxide dielectric layer incorporates nitrogen, preferably in a nitrogen/oxygen ratio of less than 0.5;
the formation of the dielectric layer comprises the formation of at least part of the dielectric layer on the donor substrate;
the application of the surface treatment comprises its application to the exposed surface of the main face of the donor substrate; and
the formation of at least part of the dielectric layer on the donor substrate precedes the application of the surface treatment.

### BRIEF DESCRIPTION OF THE DRAWINGS

Other features and advantages of the present disclosure will emerge from the following detailed description of embodiments of the disclosure with reference to the accompanying figures, in which:

FIG. 1 shows a structure according to the present disclosure;

FIG. 2 shows the sequences of a method for manufacturing a structure according to the present disclosure; and

FIG. 3 shows the sub-steps involved in the surface treatment to form a barrier layer in a method for manufacturing a structure according to the present disclosure.

### DETAILED DESCRIPTION

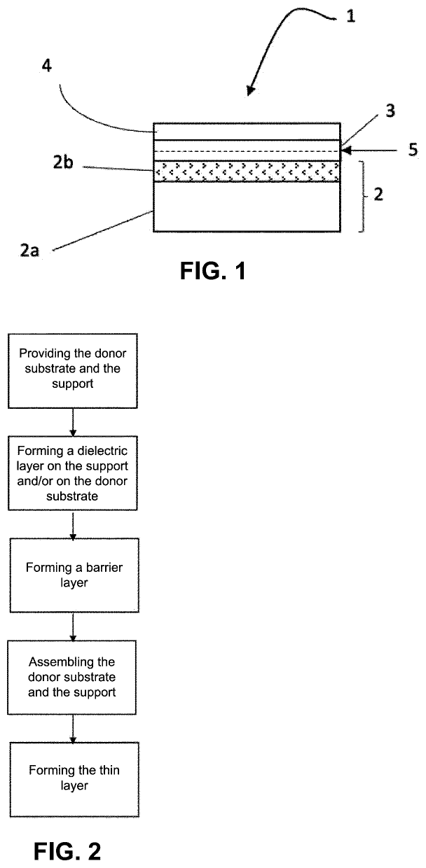

In very general terms and referring to FIG. 1, the present description relates to a method for manufacturing a structure 1 successively comprising a thin nanocrystalline layer 4, a dielectric layer 3 and a support 2. The support 2 itself comprises a base substrate 2a provided with an electric charge-trapping layer 2b. Preferably, the dielectric layer 3 is in contact with the trapping layer 2b and with the thin layer 4. As previously explained in the Background, such a structure 1 is particularly suitable for accommodating radio frequency (RF) components on or in the thin film 4.

To prevent the diffusion of certain atomic species toward the trapping layer 2b, the structure 1 comprises a barrier layer 5 arranged in the dielectric layer 3 on the structure 1 shown in FIG. 1. As will be explained in the rest of this disclosure, in addition to or instead of the barrier layer arranged in the dielectric layer, it can also be arranged superficially in, or on, the support 2 itself, or even on or in the thin layer 4 (on the side of the dielectric layer 3). The barrier layer(s) have a thickness on the order of 5 nm, typically between 2 nm and 10 nm, and are nitrogen-rich.

Atomic species liable to diffuse toward the trapping layer 2b may, in particular, come from the thin layer 4. This can be lithium, for example, when the thin layer 4 is made of lithium tantalate or lithium niobate (or, more generally, any lithium-based material). By providing a barrier layer 5 capable of blocking the diffusion of lithium between the thin layer 4 and the trapping layer 2b, RF performance degradation of the structure 1 is avoided.

The atomic species can also come from the dielectric layer 3. This is particularly the case when this layer is produced, at least in part, by deposition techniques involving moderate heat treatments below 1000° C. These treatments do not allow certain species, such as hydrogen species, to be diffused out of the deposited layer and these species are therefore likely to diffuse toward the trapping layer 2b during other steps in the manufacture of the structure 1. Once again, the presence of the barrier layer 5 blocks the diffusion of these species toward the trapping layer 2b and RF performance degradation of the structure 1 is avoided.

Conventionally, the structure 1 can be in the form of a circular wafer, the diameter of which may be 100, 150, 200, 300 or even 450 mm.

The base substrate 2a of the support 2 on which the trapping layer 2b rests typically has a thickness of several hundred micrometers. Preferably, the base substrate 2a has a high resistivity, greater than 1000 ohm·centimeters, and even more preferably, greater than 2000 ohm·centimeters. The density of the charges, holes or electrons, which are likely to move in the base substrate, is thus limited. However, the disclosure is not limited to a base substrate 2a having such a resistivity, and it also provides RF performance advantages when the base substrate has a more compliant resistivity, of the order of a few hundred ohm·centimeters, for example, less than 1000 ohm·cm, or less than 500 ohm·cm or even less than 10 ohm·cm.

For availability and cost reasons, the base substrate 2a preferably consists of monocrystalline silicon. It may, for example, be a CZ silicon substrate with a low interstitial oxygen content of between 6 and 10 ppm, or an FZ silicon substrate that particularly has a naturally very low interstitial oxygen content. It can also be a CZ silicon substrate having a high amount of interstitial oxygen (designated by the expression “High Oi”) of more than 26 ppm. The base substrate 2a may alternatively be formed from another material: it may, for example, be sapphire, glass, quartz, silicon carbide, etc. In certain circumstances and, in particular, when the trapping layer 2b is thick enough, for example, greater than 30 microns thick, the base substrate 2a may have standard resistivity, of less than 1 kohm·cm.

The trapping layer 2b can be quite varied in nature, as recorded in the documents forming the state of the art. In general, it is a non-monocrystalline layer having structural defects such as dislocations, grain boundaries, amorphous zones, interstices, inclusions, pores, etc. These structural defects form traps for the charges liable to circulate in the material, for example, at incomplete or pending chemical bonds. This prevents conduction in the trapping layer, which consequently has high resistivity.

Advantageously, and for the sake of simplicity of implementation, this trapping layer 2b is formed of a layer of polycrystalline silicon. This layer can be formed by deposition on the base substrate 2a. Its thickness, especially when it is formed on a resistive base substrate 2a, may be between 0.1 and 3 μm. However, other thicknesses below or above this range are entirely conceivable, depending on the level of RF performance expected from the structure 1.

To seek to preserve the polycrystalline quality of this layer during heat treatments that can be applied to the structure 1, an amorphous layer, consisting of silicon dioxide, for example, can advantageously be provided on the base substrate 2a before the deposition of the trapping layer 2b.

Alternatively, the trapping layer 2b may be formed by the implantation of a relatively heavy species, such as argon, in a surface thickness of the base substrate 2a, to form therein the structural defects constituting the electric traps. This layer 2b can also be formed by porosification of a surface thickness of the base substrate 2a or by any other method capable of forming structural defects in a surface thickness of the base substrate 2a, with these structural defects being capable of trapping electric charges.

The dielectric layer 3 is preferably made of silicon oxide. Other chemical elements may also be incorporated therein, either in trace amounts or in higher concentrations. In particular, this layer may incorporate nitrogen (to form a SiON layer), for example, in a nitrogen/oxygen ratio of less than 0.5. To characterize the proportion of nitrogen in the layer, a measurement of the refractive index thereof is used, which varies (at a wavelength of 620 nm) between 1.44 for SiO₂ and 2.35 for Si₃N₄.

The thin layer 4 of the structure 1 can be of any suitable type. When the structure 1 is intended to receive integrated semiconductor components, the thin layer 4 can thus be composed of monocrystalline silicon, or of any other monocrystalline semiconductor material such as germanium, silicon germanium, or silicon carbide. When the structure 1 is intended to receive surface acoustic wave filters, the thin layer 4 can be composed of a monocrystalline piezoelectric and/or ferroelectric material, such as lithium tantalate or lithium niobate. The thin layer 4 may also comprise finished or semi-finished integrated components, formed on the donor substrate and transferred onto the support 2 during the step of manufacturing the structure 1. Generally, the thin layer can be between 10 nm and 10 microns thick.

The structure 1 can be produced in many ways. Very generally, and referring to FIG. 2, the structure 1 can be made by a manufacturing method comprising:
providing the support and the donor substrate;
forming a dielectric layer on an exposed surface of a so-called “main” face of the support and/or on an exposed surface of a so-called “main” face of a donor substrate;
applying a surface treatment to the exposed surface of the main face of the support and/or to the exposed surface of the main face of the donor substrate with a view to forming thereon the barrier layer;
assembling the support and the donor substrate by their respective main faces to form an intermediate structure; and
removing part of the donor substrate from the intermediate structure to form the thin layer 4 resting on the support by way of the dielectric layer.

The dielectric layer can be made by deposition, for example, using LPCVD (low pressure chemical vapor deposition) or PECVD (plasma enhanced chemical vapor deposition) techniques. It may also be a HDP CVD (high density plasma chemical vapor deposition) technique.

A silicon oxide dielectric layer 3 can be obtained by oxidation of the donor substrate when this donor substrate is made of silicon or by oxidation of the trapping layer 2 when this layer is also made of silicon. In this second case, oxidation is followed by a step of polishing the oxidized surface to facilitate subsequent assembly of the donor substrate and the support substrate 2.

The assembly step is advantageously carried out by molecular adhesion. As is well known per se, during a molecular adhesion method, the exposed surfaces of the support and the donor substrate, which are perfectly clean, flat and smooth, are brought into close contact with one another to promote the development of molecular bonds, for example, of the van der Waals or covalent type. The two bodies are then assembled without the use of adhesives. These bonds can be strengthened by applying a heat treatment to the intermediate structure.

The step of eliminating part of the donor substrate can be carried out by chemical-mechanical thinning of this substrate. Preferably, the structure 1 is manufactured by applying Smart Cut™ technology, according to which a layer intended to form the thin layer 4 is delimited by way of an embrittlement plane formed by the implantation of light species (typically hydrogen and/or helium) into the donor substrate. After the assembly step, this layer is removed from the donor substrate by fracture at the embrittlement plane and thus transferred to the support 2.

The steps involved in the surface treatment intended to easily create the barrier layer 5 in the structure 1 during its manufacture are now described in detail.

The surface treatment is applied to the exposed surface of the main face of the support and/or to the exposed surface of the main face of the donor substrate.

When a dielectric layer has been previously formed on the main face of one of these two elements, by deposition or by oxidation, the exposed surface to which the surface treatment is applied, therefore, corresponds to the exposed surface of the dielectric layer. In very general terms, however, the surface treatment can be applied to either or both the donor substrate and the support, whether or not they have a dielectric surface layer.

The surface treatment may be applied to the exposed surface of the support and/or the donor substrate before a dielectric layer is deposited on this face in additional embodiments.

For the avoidance of doubt, it is therefore specified that the surface treatment leading to the formation of the barrier layer 5 can be applied to the donor substrate only, to the support only, or to both of these substrates. The formation of the dielectric layer may precede or follow the application of the surface treatment.

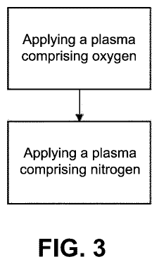

Whether the surface treatment is carried out on either or both of these two substrates, it consists of 2 successive sub-steps, as shown in FIG. 3. In a first sub-step, the exposed surface is exposed to a plasma comprising oxygen. This first sub-step leads to the formation of a porous (or more generally) damaged layer of small thickness (of the order of 5 nm, typically between 2 nm and 10 nm) on the surface or buried at a very shallow depth from the surface. The plasma to which the substrate surface has been exposed in this first step may be an oxygen plasma or an oxygen plasma combined with sulfur hexafluoride (SF₆) or with a gas having the general formula CₓH_{y}F_{z}.

In a second sub-step following the first sub-step, the exposed surface of the treated substrate is exposed to a plasma comprising nitrogen. In the second sub-step, a large quantity of nitrogen is introduced into the damaged layer formed in the first sub-step. The plasma to which the substrate surface is exposed in the second sub-step may consist of nitrogen.

It is not necessary for these 2 steps to be carried out in situ, and it is possible to expose the donor substrate or the support to the atmosphere between the first and the second sub-step.

The plasma exposure sub-steps may consist of placing the substrate concerned in a chamber of plasma activation equipment, for example, on a planar support arranged in the chamber, so as to expose the main face to the plasma prepared by a source. An oxygen-based (first sub-step) or nitrogen-based (second sub-step) stream is introduced into the plasma source for the equipment at a controlled flow rate and a plasma of this gas is generated, for example, via variable magnetic or electric fields. The plasma species are projected onto the exposed surface. These operations can be carried out at atmospheric or sub-atmospheric pressure.

This sequence of sub-steps makes it very easy to produce a relatively thin barrier, on the order of 5 nanometers, which incorporates a large quantity of nitrogen, making it particularly effective. In particular, it makes this barrier much more effective at blocking the diffusion of certain atomic species, compared with a barrier formed solely by exposure to a single nitrogen plasma.

Of course, the disclosure is not limited to the embodiment described and variant embodiments can be added thereto without departing from the scope of the invention as defined by the claims.

1. A method for manufacturing a structure comprising a thin layer transferred onto a support via a dielectric layer, the support comprising an electric charge-trapping layer arranged superficially on a base substrate, the method comprising:
forming a dielectric layer on an exposed surface of a main face of the support and/or on an exposed surface of a main face of a donor substrate;
applying a surface treatment to the exposed surface of the main face of the support and/or to the exposed surface of the main face of the donor substrate to form thereon a barrier layer forming a barrier to diffusion of atomic species;
assembling the support and the donor substrate by their respective main faces to form an intermediate structure; and
removing at least part of the donor substrate from the intermediate structure to form the thin layer;
wherein the surface treatment applied to at least one of the exposed surfaces comprises:
exposing the exposed surface to a plasma comprising oxygen to form a damaged thickness beneath the main surface, and then
exposing the exposed surface to a plasma comprising nitrogen to nitride the damaged thickness.

2. The method of claim 1, wherein the donor substrate comprises a monocrystalline piezoelectric material.

3. The method of claim 1, wherein the donor substrate is a monocrystalline silicon substrate.

4. The method of claim 1, wherein the base substrate is a monocrystalline silicon substrate.

5. The method of claim 1, wherein the dielectric layer comprises silicon oxide.

6. The method of claim 1, wherein the electric charge-trapping layer comprises polycrystalline silicon.

7. The method of claim 6, wherein the forming of the dielectric layer comprises oxidation of the electric charge-trapping layer.

8. The method of claim 7, wherein the applying the surface treatment comprises applying the surface treatment to the exposed surface of the main face of the support, and wherein the forming of the dielectric layer precedes the applying the surface treatment to the exposed surface of the main face of the support.

9. The method of claim 7, wherein the applying the surface treatment comprises applying the surface treatment to the exposed surface of the main face of the support, and wherein the forming of the dielectric layer follows the applying the surface treatment to the exposed surface of the main face of the support.

10. The method of claim 5, wherein the silicon oxide of the dielectric layer incorporates nitrogen.

11. The method of claim 1, wherein the forming of the dielectric layer comprises forming at least part of the dielectric layer on the donor substrate.

12. The method of claim 11, wherein the applying the surface treatment comprises applying the surface treatment to the exposed surface of the main face of the donor substrate.

13. The method of claim 12, wherein the forming at least part of the dielectric layer on the donor substrate precedes the applying the surface treatment.

14. The method of claim 10, wherein the silicon oxide of the dielectric layer incorporates nitrogen at a nitrogen/oxygen ratio of less than 0.5.
